(19) United States
(12) Patent Application Publication
(10) Pub. No.: US 2025/0383994 A1
(43) Pub. Date: Dec. 18, 2025

(54) LOGICAL BLOCK ADDRESS RECOVERY BY A MEMORY SYSTEM

(71) Applicant: Micron Technology, Inc., Boise, ID (US)

(72) Inventors: Xiaolai Zhu, Shanghai (CN); Huachen Li, Shanghai (CN)

(21) Appl. No.: 19/231,292

(22) Filed: Jun. 6, 2025

Related U.S. Application Data
(60) Provisional application No. 63/659,766, filed on Jun. 13, 2024.

(51) Int. Cl. G06F 12/10; G06F 11/10; G06F 12/02

(52) U.S. Cl. CPC G06F 12/10; G06F 11/1004; G06F 12/0246; G06F 2212/7205

(57) ABSTRACT

Methods, systems, and devices for logical block address recovery by a memory system are described. A memory system may identify an uncorrectable error associated with a virtual block and may update an index of the virtual block from a first index (e.g., a first value) to a second index (e.g., a second value). The memory system may determine a logical block address of the virtual block that is associated with the uncorrectable error and may update a mapping (e.g., a logical-to-physical (L2P) mapping) between the logical block address and a physical block of the memory system.

### CROSS REFERENCE

The present Application for Patent claims priority to U.S. Patent Application No. 63/659,766 by Zhu et al., entitled “LOGICAL BLOCK ADDRESS RECOVERY BY A MEMORY SYSTEM,” filed Jun. 13, 2024, which is assigned to the assignee hereof, and which is expressly incorporated by reference in its entirety herein.

### TECHNICAL FIELD

The following relates to one or more systems for memory, including logical block address recovery by a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports logical block address recovery by a memory system in accordance with examples as disclosed herein.

FIG. 2 shows an example of a block diagram that supports logical block address recovery by a memory system in accordance with examples as disclosed herein.

FIG. 3 shows an example of a block diagram that supports logical block address recovery by a memory system in accordance with examples as disclosed herein.

FIG. 4 shows an example of a process that supports logical block address recovery by a memory system in accordance with examples as disclosed herein.

FIG. 5 shows a block diagram of a memory system that supports logical block address recovery by a memory system in accordance with examples as disclosed herein.

FIG. 6 shows a flowchart illustrating a method or methods that support logical block address recovery by a memory system in accordance with examples as disclosed herein.

### DETAILED DESCRIPTION

Some memory systems (e.g., NAND memory systems) may store data to one or more virtual blocks. A virtual block may refer to a group of blocks (e.g., a group of physical blocks) within which concurrent operations may occur. The memory system may maintain one or more tables (e.g., page valid tables (PVTs), physical page tables (PPTs), logical-to-physical (L2P) tables) that maintain mappings between logical addresses and physical addresses of a virtual block, and indications of whether data stored to a virtual block is valid or invalid. In some instances, valid data may be moved from a source virtual block to a destination virtual block during a maintenance operation (e.g., a garbage collection operation). When the valid data is moved, one or more tables may be updated to map the logical block address to the physical address of the destination virtual block.

In some instances, data stored to a virtual block may be valid but may otherwise become unreadable due to an error (e.g., the memory system may experience an uncorrectable error correction code (UECC)). During a maintenance operation, valid data may be moved to a destination virtual block, and the source virtual block may be erased. However, the associated entry in a table may still map a logical block address to the physical address of the source virtual block associated with the error. In such instances, the source virtual block may not be used (e.g., reused) until the mapping is updated. That is, without updating the mapping, incorrect data may be reported (e.g., transmitted) to a host system. Thus, the memory system may perform a recovery operation to update the mapping between the logical block address associated with the error and a physical address of a virtual block. Such recovery operations are performed in the foreground of a memory system, which impacts the latency and overall performance of the memory system. Accordingly, a memory system configured to perform such mapping recovery operations in the background may be desirable.

A memory system configured to perform mapping recovery operations in the background is described herein. In some examples, a memory system may manage a bad block table (BBT) in addition to PVTs and L2P tables. A BBT may include mappings between virtual blocks and associated physical blocks of the memory system. For example, the BBT may indicate that virtual block VB0 is mapped to physical block PB0, virtual block VB1 is mapped to physical block PB1, and so on. When a maintenance operation occurs (e.g., when data is moved from one physical block to another), the mapping between the virtual block and the new physical block may be updated.

To enable mapping recovery operations to be performed in the background, the BBT may include one or more additional indices reserved for mapping recovery operations. When a maintenance operation is to be performed on a source virtual block (e.g., VB0), the index associated with the source virtual block may be updated to one of the reserved indices. For example, the index VB0 may be updated to be the index VB500, and the BBT table may indicate that VB500 is mapped to PB0. Accordingly, the memory system may continue using PB0 (e.g., after its data is erased during the maintenance operation), while a mapping recovery operation is performed on VB0 in the background. That is, the memory system may identify and update, in the background, the mapping of logical block addresses of VB0 that are associated with an error. By performing such mapping recovery operations in the background, the latency and performance of the memory system may be improved.

In addition to applicability in memory systems as described herein, techniques for logical block address recovery may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing latency and improving the overall performance of the memory system, among other benefits.

Features of the disclosure are illustrated and described in the context of systems, devices, and circuits. Features of the disclosure are further illustrated and described in the context of block diagrams and flowcharts.

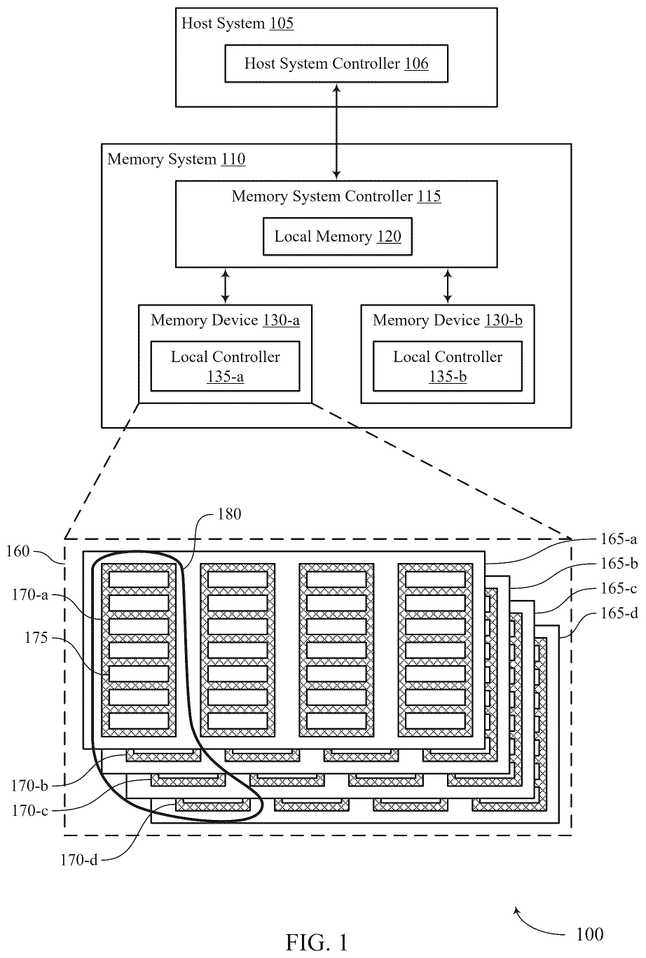

FIG. 1 shows an example of a system 100 that supports logical block address recovery by a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some examples, the memory system 110 may manage a BBT in addition to PVTs and L2P tables. A BBT may include mappings between virtual blocks 180 and associated physical blocks 170 of the memory system 110. For example, the BBT may indicate that virtual block VB0 is mapped to physical block PB0, virtual block VB1 is mapped to physical block PB1, and so on. When a maintenance operation occurs (e.g., when data is moved from one physical block to another), the mapping between the virtual block 180 and the new physical block 170 may be updated.

To enable mapping recovery operations to be performed in the background, the BBT may include one or more additional indices reserved for mapping recovery operations. When a maintenance operation is to be performed on a source virtual block 180 (e.g., VB0), the index associated with the source virtual block 180 may be updated to one of the reserved indices. For example, the index VB0 may be updated to be the index VB500, and the BBT table may indicate that VB500 is mapped to PB0. Accordingly, the memory system 110 may continue using PB0 (e.g., after its data is erased during the maintenance operation), a mapping recovery operation is performed on VB0 in the background. That is, the memory system 110 (e.g., the memory system controller 115) may identify and update, in the background, the mapping of logical block addresses of VB0 that are associated with an error. By performing such mapping recovery operations in the background, the latency and performance of the memory system 110 may be improved.

The system 100 may include any quantity of non-transitory computer readable media that support logical block address recovery by a memory system. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

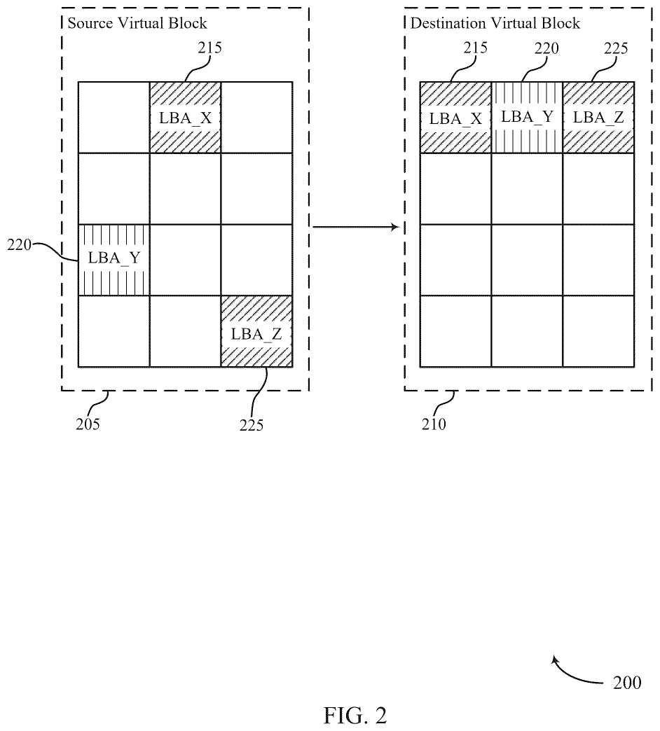

FIG. 2 shows an example of a block diagram 200 that supports logical block address recovery by a memory system in accordance with examples as disclosed herein. The block diagram 200 may illustrate a source virtual block 205 (e.g., a first virtual block 205) and a destination virtual block 210 (e.g., a second virtual block 210). The block diagram 200 may illustrate aspects of a maintenance operation (e.g., a garbage collection operation) where valid data is moved from the source virtual block 205 to the destination virtual block 210. In some examples, the maintenance operation may be performed on first data 215 associated with a first logical block address, second data 220 associated with a second logical block address, and third data 230 associated with a third logical block address. The maintenance operation described with reference to FIG. 2 may support mapping recovery operations being performed in the background, which may improve the overall latency and performance of an associated memory system.

As used herein, “background” or a “background operation” may refer to an operation (or operations) that is performed when a memory system is in an idle state, or when a quantity of host commands is relatively low. Background operations may utilize relatively fewer resources than foreground operations. That is, a foreground operation may have a relatively greater impact on the bandwidth and available processing capabilities of a memory system than background operations due to foreground operations being added to a same queue as host commands. By performing mapping recovery operations in the background as described herein, an associated memory system may preserve resources, thus improving its overall latency and performance.

A virtual block may refer to a group of blocks (e.g., a group of physical blocks) within which concurrent operations may occur. For example, the source virtual block 205 may be associated with twelve (12) physical blocks, and each physical block may be associated with a respective logical block address. The mapping between logical block addresses and physical blocks of a virtual block may be maintained by a PPT, an L2P table, or both. As used herein, a PPT and a L2P table may each refer to a table that stores mappings between logical addresses and physical addresses. Accordingly, a PPT may refer to an L2P and vice versa.

For example, the first data 215 may be associated with a first logical block address (e.g., LBA_x) and may be mapped to a second physical block of the source virtual block 205. The second data 220 may be associated with a second logical block address (e.g., LBA_y) and may be mapped to a seventh physical block of the source virtual block 205, and the third data 225 may be associated with a third logical block address (e.g., LBA_z) and may be mapped to a twelfth physical block of the source virtual block 205.

In some instances, the first data 215, the second data 220, and the third data 225 may be valid data, and the remaining physical blocks of the source virtual block 205 (e.g., the first, third, fourth, fifth, sixth, eighth, ninth, tenth, and eleventh physical blocks) may store invalid data or no data. The validity of the data may be maintained by a PVT. For example, as shown below in Table 1, a PVT may include a value corresponding to each physical block of a virtual block.

TABLE 1

| | | |
|---|---|---|
| 0 | 1 | 0 |
| 0 | 0 | 0 |
| 1 | 0 | 0 |
| 0 | 0 | 1 |

By way of example, the table may include a ‘0’ to indicate no data or invalid data, and may include a ‘1’ to indicate valid data. The data may be moved (e.g., transferred) from the physical blocks of the source virtual block 205 that associated with a ‘1’ to physical blocks of the destination virtual block 210. The physical blocks associated with a ‘0’ may be erased during a maintenance operation.

In some instances, an error may occur with a hardware component, such as one or more physical blocks of the source virtual block 205 (or other physical blocks of an associated memory system). For example, the second data 220 may be valid, but the associated physical block may experience a defect that may result in the data not being able to be read out (e.g., transferred) to a host system. Such errors may be or may be referred to as uncorrectable errors. In other instances, an uncorrectable error may refer to any hardware-related error that results in data being unable to be read.

The data associated with the uncorrectable error (e.g., the second data 220) may be moved to a destination virtual block 210 during a maintenance operation, but the associated entry in a L2P table may still map to (e.g., point to) the physical block address of the source virtual block 205. That is, because the second data 220 may be associated with an uncorrectable error, its logical block address may be unknown (e.g., unknown until a mapping recovery operation is performed). Thus, after the second data 220 is moved to the destination virtual block 210, the L2P table may still map the logical block address of the second data 220 to the physical block address of the source virtual block 205. Accordingly, if a read command is received for the logical block address of the second data 220, incorrect data may be transmitted to the host due to the L2P table including the incorrect mapping. Additionally, or alternatively, the source virtual block 205 may be unusable until the maintenance operation is complete (e.g., until the logical block address of the second data 220 is recovered).

When data is moved from a source block 205 to a destination virtual block 210 during a maintenance operation, respective entries in a L2P table may be updated. For example, when the first data 215 and the third data 225 are moved to the destination virtual block 210, respective entries may be created in a change log. For example, the entries may indicate the updated mapping between the logical block addresses and physical block addresses of the destination virtual block 210 for the first data 215 and the third data 225. The change log entries may be merged with the L2P table. Thus, when a read command is received for the first data 215 or the third data 225, the data may be read out (e.g., read out correctly) from the physical block addresses of the destination virtual block 210.

When the second data 220 is moved from the source virtual block 205 to the destination virtual block 210, a mapping recovery operation may be performed due to the uncorrectable error associated with the second data 220. In some examples, a mapping recovery operation (e.g., a PPT recovery operation, a L2P recovery operation) may be performed to identify the logical block address associated with the second data 220 and update the mapping between the identified logical block address and the physical block address of the destination virtual block 210 to which the second data 220 was moved.

To perform a mapping recovery operation, a portion or all of a L2P table may be loaded (e.g., to a volatile memory of the memory system), and each of the mappings may be scanned (e.g., reviewed, analyzed) to identify the logical block addresses that are mapped to the source virtual block 205. For example, only the logical block address associated with the second data 220 may map to a physical block address associated with the source virtual block 205 due to the other mappings (e.g., the mappings for the first data 215 and the third data 225) indicating (e.g., pointing to) physical block addresses of the destination virtual block 210. Accordingly, such a mapping recovery operation may identify the logical block address of the second data, and the mapping may be updated to indicate (e.g., point to) a physical block address of the destination virtual block 210. As described herein, the mapping recovery operation may be performed in the background which may improve the overall latency and performance of the associated memory system.

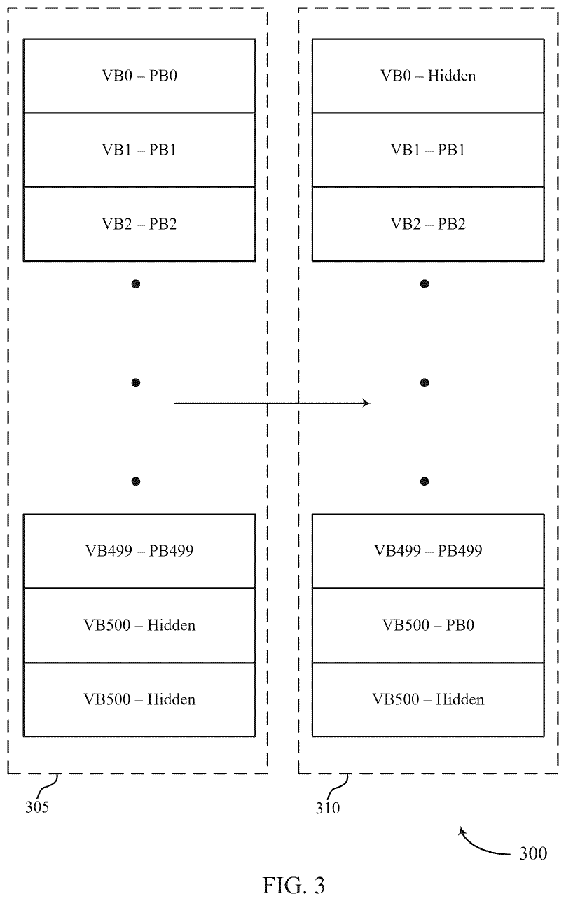

FIG. 3 shows an example of a block diagram 300 that supports logical block address recovery by a memory system in accordance with examples as disclosed herein. The block diagram 300 may show an initial BBT 305 and an updated BBT 310. For example, the initial BBT 305 may include first mappings between virtual blocks and physical blocks of a memory system. The updated BBT 310 may include updated mappings between the virtual blocks and the physical blocks, which may allow for a mapping recovery operation to be performed as a background operation. As described herein, performing mapping recovery operations in the background may improve the overall latency and performance of an associated memory system.

As described with reference to FIG. 2, a source virtual block 205 and a destination virtual block 210 may each be associated with a respective index. For example, the source virtual block 205 may be associated with index ‘VB0’ and the destination virtual block 210 may be associated with index ‘VB1’. Each virtual block within a memory system may be associated with a respective index, as shown in FIG. 3. For example, a memory system may include five hundred (500) virtual blocks, each having an index ranging from VB0 to VB499. In other examples, a memory system may include any quantity of virtual blocks and any corresponding quantity of indices.

The memory system herein may include (e.g., maintain) one or more additional indices to enable mapping recovery operations to be performed in the background. For example, the memory system may include index VB500 and index VB501, which may be “hidden” indices. A hidden index may refer to any index that is not mapped to a corresponding physical block at a given time. That is, in the initial BBT 305, VB500 and VB501 may not be mapped to corresponding physical blocks of the memory system.

During a maintenance operation (e.g., when a mapping recovery operation is to be performed), the index of a source virtual block may be updated. For example, when the unrecoverable error associated with the source virtual block 205 is identified and the mapping recovery operation is to be performed, the memory system (e.g., a memory system controller) may update the index of the source virtual block 205. In some examples, updating the index may include assigning a new (e.g., an updated) index to the source virtual block 205. For example, the initial BBT 305 may have been VB0−PB0. However, the index VB0 may be unassigned and VB500 may be assigned to the source virtual block 205. Thus, the updated BBT 310 may include the mapping VB500−PB0. Additionally, or alternatively, the updated mapping of VB0 may be VB0-Hidden.

Because the index of the source virtual block 205 is updated from VB0 to VB500, the physical blocks (e.g., PB0) may be accessed while a mapping recovery operation is performed on VB0. That is, by updating the mapping of VB0 to VB500, the physical blocks may be accessible before the maintenance operation is completed (e.g., before the mapping recovery operation is performed). Moreover, the mapping recovery operation may be performed in the background, while foreground operations are performed (e.g., while other physical blocks, including PB0, are accessed). After the mapping recovery operation is performed on VB0, the virtual block (e.g., the source virtual block 205) may be released into a pool of free blocks. That is, after the mapping recovery operation is performed on VB0, VB0 may be written to or may otherwise be accessible. As described herein, performing mapping recovery operations in the background may improve the overall latency and performance of an associated memory system.

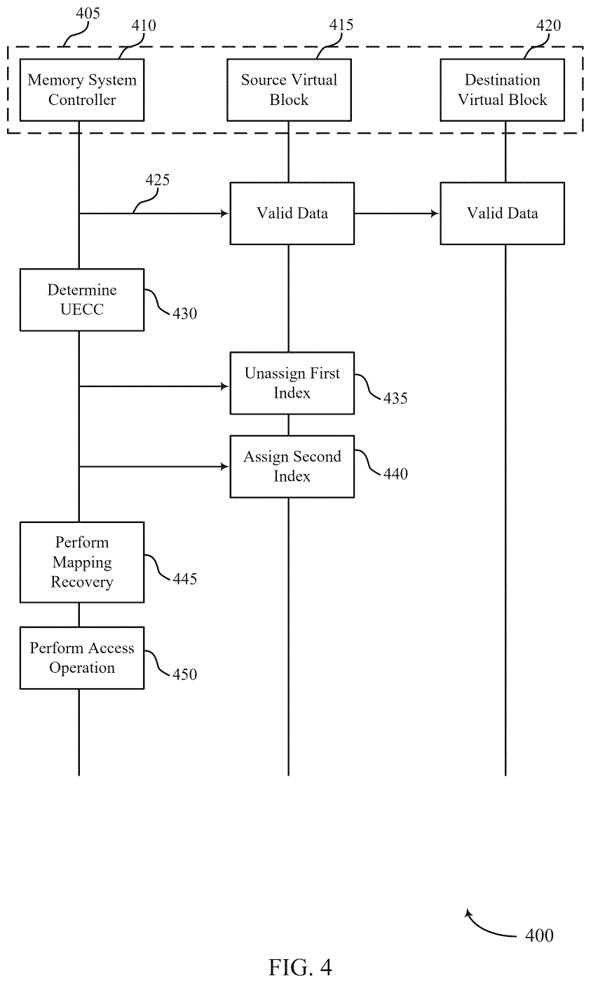

FIG. 4 shows an example of a process 400 that supports logical block address recovery by a memory system in accordance with examples as disclosed herein. In some examples, the process 400 may illustrate operations performed at a memory system 405 by a memory system controller 410. The memory system 405 may include a source virtual block 415 and a destination virtual block 420, which may be examples of the source virtual block 205 and the destination virtual block 210 as described with reference to FIG. 2. In some instances, the memory system controller 410 may maintain or otherwise manage the tables (e.g., a PVT, a PPT, an L2P table, a BBT) as described herein with reference to FIGS. 2 and 3. The memory system 405 may support performing mapping recovery operations in the background, which may improve the overall latency and performance of the memory system 405.

Aspects of the process 400 may be implemented by one or more controllers, among other components. Additionally, or alternatively, aspects of the process 400 may be implemented as instructions stored in one or more memories (e.g., firmware stored in one or more memories coupled with the memory system controller). For example, the instructions, when executed by one or more controllers (e.g., the memory system controller 115 as described with reference to FIG. 1), may cause the one or more controllers (or a device or a system) to perform the operations of the process 400.

At 425, valid data may be moved. In some instances, valid data may be moved from the source virtual block 415 to the destination virtual block 420 as part of a maintenance operation (e.g., as part of a garbage collection operation). The valid data may be moved by the memory system controller 410. The first data 215, the second data 220, and the third data 225 may be examples of the valid data moved at 425.

At 430, an uncorrectable error (UECC) may be determined. In some examples, the memory system controller 410 may determine the UECC as part of a maintenance operation. For example, the memory system controller 410 may determine the UECC when moving the valid data (e.g., at 425). As described herein, the memory system controller 410 may be unable to identify the logical block address of the physical block address associated with the uncorrectable error. In some instances, the source virtual block 415 may be associated with the uncorrectable error and the memory system controller 410 may initiate a mapping recovery operation to identify (e.g., recover) the logical block address.

At 435, the first index may be unassigned from the source virtual block 415. In some instances, the memory system controller 410 may unassign the index VB0 from the source virtual block 415 based on identifying the uncorrectable error. As described with reference to FIG. 3, the unassigned index may be “Hidden,” such that the mapping recovery operation may be performed in the background.

At 440, the second index may be assigned to the source virtual block 415. In some instances, the memory system controller 410 may assign the index VB500 to the source virtual block 415 based on unassigning the first index (e.g., VB0). As described with reference to FIG. 3, the updated BBT mapping may be VB500−PB0, which may allow for PB0 to be accessed while the mapping recovery operation is performed.

At 445, the mapping recovery operation may be performed. In some instances, the mapping recovery operation may be performed by the memory system controller 410. To perform the mapping recovery operation, the memory system controller 410 may load a portion or all of an L2P table to volatile memory, and each of the mappings may be scanned (e.g., reviewed, analyzed) to identify the logical block addresses that are mapped to the source virtual block 415. For example, only the logical block address of the data associated with the uncorrectable error may map to a physical block address associated with VB0 due to the other mappings (e.g., the mappings for the first data 215 and the third data 225) indicating (e.g., pointing to) physical block addresses of the destination virtual block 420. Accordingly, such a mapping recovery operation may identify the logical block address of data associated with the uncorrectable error, and the mapping may be updated to indicate (e.g., point to) a physical block address of the destination virtual block 420.

At 450, access operations may be performed. In some instances, access operations may be performed by the memory system controller 410 on PB0 (e.g., on VB500) due to the first index being unassigned (e.g., at 435) and the second index being assigned (e.g., at 440). As described herein, performing mapping recovery operations in the background may improve the overall latency and performance of the memory system 405.

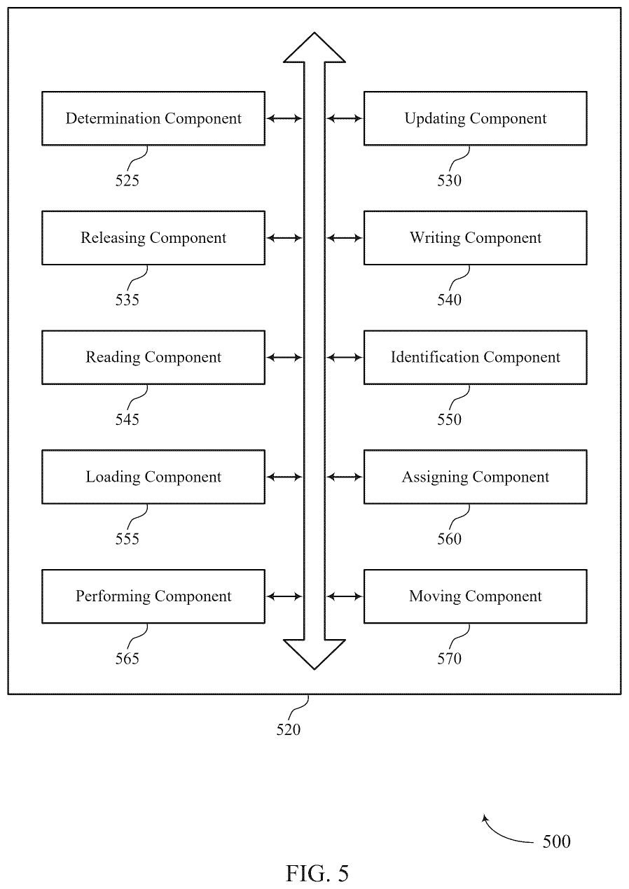

FIG. 5 shows a block diagram 500 of a memory system 520 that supports logical block address recovery by a memory system in accordance with examples as disclosed herein. The memory system 520 may be an example of aspects of a memory system as described with reference to FIGS. 1 through 4. The memory system 520, or various components thereof, may be an example of means for performing various aspects of logical block address recovery by a memory system as described herein. For example, the memory system 520 may include a determination component 525, an updating component 530, a releasing component 535, a writing component 540, a reading component 545, an identification component 550, a loading component 555, an assigning component 560, a performing component 565, a moving component 570, or any combination thereof. Each of these components, or components of subcomponents thereof (e.g., one or more processors, one or more memories), may communicate, directly or indirectly, with one another (e.g., via one or more buses).

The determination component 525 may be configured as or otherwise support a means for determining whether a first virtual block of the memory system includes an uncorrectable error in response to performing a garbage collection operation on the first virtual block, where the first virtual block is associated with a first index and includes a plurality of logical block addresses each associated with a respective physical block address. The updating component 530 may be configured as or otherwise support a means for updating the first index of the first virtual block to be a second index in response to determining that the first virtual block includes the uncorrectable error. In some examples, the determination component 525 may be configured as or otherwise support a means for determining a logical block address of the first virtual block that includes the uncorrectable error in response to updating the first index to the second index. In some examples, the updating component 530 may be configured as or otherwise support a means for updating, as part of a background operation, a logical-to-physical mapping for the logical block address in accordance with the logical block address including the uncorrectable error and updating the first index to be the second index.

In some examples, the releasing component 535 may be configured as or otherwise support a means for releasing the first virtual block to a pool of free blocks for use by write operations in response to updating the logical-to-physical mapping. In some examples, the writing component 540 may be configured as or otherwise support a means for writing data to the first virtual block in response to releasing the first virtual block.

In some examples, to support updating the logical-to-physical mapping for the logical block address, the reading component 545 may be configured as or otherwise support a means for reading data from a physical address associated with the first virtual block. In some examples, to support updating the logical-to-physical mapping for the logical block address, the identification component 550 may be configured as or otherwise support a means for identifying the logical block address in response to reading the data from the physical address associated with the first virtual block.

In some examples, to support determining the logical block address of the first virtual block that includes the uncorrectable error, the loading component 555 may be configured as or otherwise support a means for loading, to a volatile memory of the memory system, a plurality of logical-to-physical mappings. In some examples, to support determining the logical block address of the first virtual block that includes the uncorrectable error, the determination component 525 may be configured as or otherwise support a means for determining that the logical block address is the only logical block address mapped to a physical address associated with the first virtual block in response to loading the plurality of logical-to-physical mappings to the volatile memory.

In some examples, to support updating the first index of the first virtual block, the assigning component 560 may be configured as or otherwise support a means for unassigning the first index from the first virtual block. In some examples, to support updating the first index of the first virtual block, the assigning component 560 may be configured as or otherwise support a means for assigning the second index to the first virtual block.

In some examples, the second index was unassigned prior to being assigned to the first virtual block.

In some examples, the performing component 565 may be configured as or otherwise support a means for performing the garbage collection operation on the first virtual block, where performing the garbage collection operation includes erasing data stored to one or more physical block addresses in response to updating the logical-to-physical mapping for the logical block address, where writing data to the first virtual block is in response to erasing the data stored to the one or more physical block addresses.

In some examples, the moving component 570 may be configured as or otherwise support a means for moving, as part of the garbage collection operation, a plurality of valid data from the first virtual block to a second virtual block. In some examples, the updating component 530 may be configured as or otherwise support a means for updating, for logical block addresses associated with the plurality of valid data, logical-to-physical mappings for logical block addresses associated with the plurality of valid data in response to moving the plurality of valid data from the first virtual block to the second virtual block.

In some examples, the determination component 525 may be configured as or otherwise support a means for determining that the memory system is in an idle state, where determining the logical block address of the first virtual block and updating the logical-to-physical mapping for the logical block address occur in response to the memory system being in the idle state.

In some examples, the memory system includes a quantity of unassigned virtual block indices.

In some examples, the writing component 540 may be configured as or otherwise support a means for writing data to a third virtual block including the first index in response to updating the first index to the second index.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

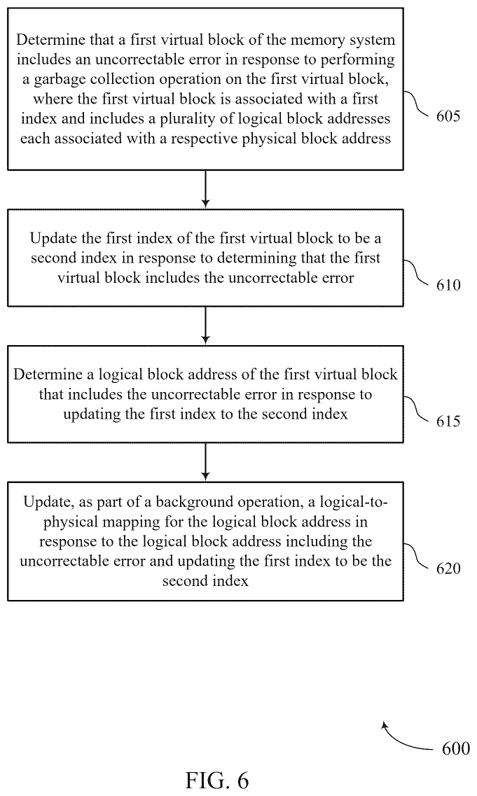

FIG. 6 shows a flowchart illustrating a method 600 that supports logical block address recovery by a memory system in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include determining whether a first virtual block of the memory system includes an uncorrectable error in response to performing a garbage collection operation on the first virtual block, where the first virtual block is associated with a first index and includes a plurality of logical block addresses each associated with a respective physical block address. In some examples, aspects of the operations of 605 may be performed by a determination component 525 as described with reference to FIG. 5.

At 610, the method may include updating the first index of the first virtual block to be a second index in response to determining that the first virtual block includes the uncorrectable error. In some examples, aspects of the operations of 610 may be performed by an updating component 530 as described with reference to FIG. 5.

At 615, the method may include determining a logical block address of the first virtual block that includes the uncorrectable error in response to updating the first index to the second index. In some examples, aspects of the operations of 615 may be performed by a determination component 525 as described with reference to FIG. 5.

At 620, the method may include updating, as part of a background operation, a logical-to-physical mapping for the logical block address in response to the logical block address including the uncorrectable error and updating the first index to be the second index. In some examples, aspects of the operations of 620 may be performed by an updating component 530 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for determining whether a first virtual block of the memory system includes an uncorrectable error in response to performing a garbage collection operation on the first virtual block, where the first virtual block is associated with a first index and includes a plurality of logical block addresses each associated with a respective physical block address; updating the first index of the first virtual block to be a second index in response to determining that the first virtual block includes the uncorrectable error; determining a logical block address of the first virtual block that includes the uncorrectable error in response to updating the first index to the second index; and updating, as part of a background operation, a logical-to-physical mapping for the logical block address in response to the logical block address including the uncorrectable error and updating the first index to be the second index.

Aspect 2: The method, apparatus, or non-transitory computer-readable medium of aspect 1, further including operations, features, circuitry, logic, means, or instructions, or any combination thereof for releasing the first virtual block to a pool of free blocks for use by write operations in response to updating the logical-to-physical mapping and writing data to the first virtual block in response to releasing the first virtual block.

Aspect 3: The method, apparatus, or non-transitory computer-readable medium of any of aspects 1 through 2, where updating the logical-to-physical mapping for the logical block address includes operations, features, circuitry, logic, means, or instructions, or any combination thereof for reading data from a physical address associated with the first virtual block and identifying the logical block address in response to reading the data from the physical address associated with the first virtual block.

Aspect 4: The method, apparatus, or non-transitory computer-readable medium of any of aspects 1 through 3, where determining the logical block address of the first virtual block that includes the uncorrectable error includes operations, features, circuitry, logic, means, or instructions, or any combination thereof for loading, to a volatile memory of the memory system, a plurality of logical-to-physical mappings and determining that the logical block address is the only logical block address mapped to a physical address associated with the first virtual block in response to loading the plurality of logical-to-physical mappings to the volatile memory.

Aspect 5: The method, apparatus, or non-transitory computer-readable medium of any of aspects 1 through 4, where updating the first index of the first virtual block includes operations, features, circuitry, logic, means, or instructions, or any combination thereof for unassigning the first index from the first virtual block and assigning the second index to the first virtual block.

Aspect 6: The method, apparatus, or non-transitory computer-readable medium of aspect 5, where the second index was unassigned prior to being assigned to the first virtual block.

Aspect 7: The method, apparatus, or non-transitory computer-readable medium of any of aspects 1 through 6, further including operations, features, circuitry, logic, means, or instructions, or any combination thereof for performing the garbage collection operation on the first virtual block, where performing the garbage collection operation includes erasing data stored to one or more physical block addresses in response to updating the logical-to-physical mapping for the logical block address, where writing data to the first virtual block is in response to erasing the data stored to the one or more physical block addresses.

Aspect 8: The method, apparatus, or non-transitory computer-readable medium of aspect 7, further including operations, features, circuitry, logic, means, or instructions, or any combination thereof for moving, as part of the garbage collection operation, a plurality of valid data from the first virtual block to a second virtual block and updating, for logical block addresses associated with the plurality of valid data, logical-to-physical mappings for logical block addresses associated with the plurality of valid data in response to moving the plurality of valid data from the first virtual block to the second virtual block.

Aspect 9: The method, apparatus, or non-transitory computer-readable medium of any of aspects 1 through 8, further including operations, features, circuitry, logic, means, or instructions, or any combination thereof for determining that the memory system is in an idle state, where determining the logical block address of the first virtual block and updating the logical-to-physical mapping for the logical block address occur in accordance with the memory system being in the idle state.

Aspect 10: The method, apparatus, or non-transitory computer-readable medium of any of aspects 1 through 9, where the memory system includes a quantity of unassigned virtual block indices.

Aspect 11: The method, apparatus, or non-transitory computer-readable medium of any of aspects 1 through 10, further including operations, features, circuitry, logic, means, or instructions, or any combination thereof for writing data to a third virtual block including the first index in response to updating the first index to the second index.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
determine whether a first virtual block of the memory system includes an uncorrectable error in response to performing a garbage collection operation on the first virtual block, wherein the first virtual block is associated with a first index and comprises a plurality of logical block addresses each associated with a respective physical block address;
update the first index of the first virtual block to be a second index in response to determining that the first virtual block includes the uncorrectable error;
determine a logical block address of the first virtual block that includes the uncorrectable error in response to updating the first index to the second index; and
update, as part of a background operation, a logical-to-physical mapping for the logical block address in response to the logical block address including the uncorrectable error and updating the first index to be the second index.

2. The memory system of claim 1, wherein the processing circuitry is further configured to cause the memory system to:
release the first virtual block to a pool of free blocks for use by write operations in response to updating the logical-to-physical mapping; and
write data to the first virtual block in response to releasing the first virtual block.

3. The memory system of claim 1, wherein to update the logical-to-physical mapping for the logical block address, the processing circuitry is configured to cause the memory system to:
read data from a physical address associated with the first virtual block; and
identify the logical block address in response to reading the data from the physical address associated with the first virtual block.

4. The memory system of claim 1, wherein to determine whether logical block address of the first virtual block includes the uncorrectable error, the processing circuitry is configured to cause the memory system to:
load, to a volatile memory of the memory system, a plurality of logical-to-physical mappings; and
determine that the logical block address is the only logical block address mapped to a physical address associated with the first virtual block in response to loading the plurality of logical-to-physical mappings to the volatile memory.

5. The memory system of claim 1, wherein to update the first index of the first virtual block, the processing circuitry is configured to cause the memory system to:
unassign the first index from the first virtual block; and
assign the second index to the first virtual block.

6. The memory system of claim 5, wherein the second index was unassigned prior to being assigned to the first virtual block.

7. The memory system of claim 1, wherein the processing circuitry is further configured to cause the memory system to:
perform the garbage collection operation on the first virtual block, wherein performing the garbage collection operation comprises erasing data stored to one or more physical block addresses in response to updating the logical-to-physical mapping for the logical block address, wherein writing data to the first virtual block is in response to erasing the data stored to the one or more physical block addresses.

8. The memory system of claim 7, wherein the processing circuitry is further configured to cause the memory system to:
move, as part of the garbage collection operation, a plurality of valid data from the first virtual block to a second virtual block; and
update, for logical block addresses associated with the plurality of valid data, logical-to-physical mappings for logical block addresses associated with the plurality of valid data in response to moving the plurality of valid data from the first virtual block to the second virtual block.

9. The memory system of claim 1, wherein the processing circuitry is further configured to cause the memory system to:
determine that the memory system is in an idle state, wherein determining the logical block address of the first virtual block and updating the logical-to-physical mapping for the logical block address occur in accordance with the memory system being in the idle state.

10. The memory system of claim 1, wherein the memory system comprises a quantity of unassigned virtual block indices.

11. The memory system of claim 1, wherein the processing circuitry is further configured to cause the memory system to:
write data to a third virtual block comprising the first index in response to updating the first index to the second index.

12. A non-transitory computer-readable medium storing code comprising instructions which, when executed by one or more processors of a memory system, cause the memory system to:
determine whether a first virtual block of the memory system includes an uncorrectable error in response to performing a garbage collection operation on the first virtual block, wherein the first virtual block is associated with a first index and comprises a plurality of logical block addresses each associated with a respective physical block address;
update the first index of the first virtual block to be a second index in response to determining that the first virtual block includes the uncorrectable error;
determine a logical block address of the first virtual block that includes the uncorrectable error in response to updating the first index to the second index; and
update, as part of a background operation, a logical-to-physical mapping for the logical block address in response to the logical block address including the uncorrectable error and updating the first index to be the second index.

13. The non-transitory computer-readable medium of claim 12, wherein the instructions, when executed by the one or more processors of the memory system, further cause the memory system to:
release the first virtual block to a pool of free blocks for use by write operations in response to updating the logical-to-physical mapping; and
write data to the first virtual block in response to releasing the first virtual block.

14. The non-transitory computer-readable medium of claim 12, wherein the instructions to update the logical-to-physical mapping for the logical block address, when executed by the one or more processors of the memory system, further cause the memory system to:
read data from a physical address associated with the first virtual block; and
identify the logical block address in response to reading the data from the physical address associated with the first virtual block.

15. The non-transitory computer-readable medium of claim 12, wherein the instructions to determine whether the logical block address of the first virtual block includes the uncorrectable error, when executed by the one or more processors of the memory system, further cause the memory system to:
load, to a volatile memory of the memory system, a plurality of logical-to-physical mappings; and
determine that the logical block address is the only logical block address mapped to a physical address associated with the first virtual block in response to loading the plurality of logical-to-physical mappings to the volatile memory.

16. The non-transitory computer-readable medium of claim 12, wherein the instructions to update the first index of the first virtual block, when executed by the one or more processors of the memory system, further cause the memory system to:
unassign the first index from the first virtual block; and
assign the second index to the first virtual block.

17. The non-transitory computer-readable medium of claim 16, wherein the second index was unassigned prior to being assigned to the first virtual block.

18. The non-transitory computer-readable medium of claim 12, wherein the instructions, when executed by the one or more processors of the memory system, further cause the memory system to:
perform the garbage collection operation on the first virtual block, wherein performing the garbage collection operation comprises erasing data stored to one or more physical block addresses in response to updating the logical-to-physical mapping for the logical block address, wherein writing data to the first virtual block is in response to erasing the data stored to the one or more physical block addresses.

19. The non-transitory computer-readable medium of claim 18, wherein the instructions, when executed by the one or more processors of the memory system, further cause the memory system to:
move, as part of the garbage collection operation, a plurality of valid data from the first virtual block to a second virtual block; and
update, for logical block addresses associated with the plurality of valid data, logical-to-physical mappings for logical block addresses associated with the plurality of valid data in response to moving the plurality of valid data from the first virtual block to the second virtual block.

20. The non-transitory computer-readable medium of claim 12, wherein the instructions, when executed by the one or more processors of the memory system, further cause the memory system to:
determine that the memory system is in an idle state, wherein determining the logical block address of the first virtual block and updating the logical-to-physical mapping for the logical block address occur in response to the memory system being in the idle state.

21. The non-transitory computer-readable medium of claim 12, wherein the memory system comprises a quantity of unassigned virtual block indices.

22. The non-transitory computer-readable medium of claim 12, wherein the instructions, when executed by the one or more processors of the memory system, further cause the memory system to:
write data to a third virtual block comprising the first index in response to updating the first index to the second index.

23. A method by a memory system, comprising:
determining whether a first virtual block of the memory system includes an uncorrectable error in response to performing a garbage collection operation on the first virtual block, wherein the first virtual block is associated with a first index and comprises a plurality of logical block addresses each associated with a respective physical block address;
updating the first index of the first virtual block to be a second index in response to determining that the first virtual block includes the uncorrectable error;
determining a logical block address of the first virtual block that includes the uncorrectable error in response to updating the first index to the second index; and
updating, as part of a background operation, a logical-to-physical mapping for the logical block address in response to the logical block address including the uncorrectable error and updating the first index to be the second index.

24. The method of claim 23, further comprising:
releasing the first virtual block to a pool of free blocks for use by write operations in response to updating the logical-to-physical mapping; and
writing data to the first virtual block in response to releasing the first virtual block.

25. The method of claim 23, wherein updating the logical-to-physical mapping for the logical block address comprises:
reading data from a physical address associated with the first virtual block; and
identifying the logical block address in response to reading the data from the physical address associated with the first virtual block.
